(19) United States
(12) Patent Application Publication
(10) Pub. No.: US 2013/0175671 A1
(43) Pub. Date: Jul. 11, 2013

(54) METHODS FOR PROCESSING A SEMICONDUCTOR WAFER, A SEMICONDUCTOR WAFER AND A SEMICONDUCTOR DEVICE

(71) Applicants: Philippe Renaud, Cugnaux (FR); Roland Serrano, Toulouse (FR)

(72) Inventors: Philippe Renaud, Cugnaux (FR); Roland Serrano, Toulouse (FR)

(73) Assignee: Freescale Semiconductor, Inc., Austin, TX (US)

(21) Appl. No.: 13/821,070

(22) PCT Filed: Sep. 30, 2010
(86) PCT No.: PCT/IB10/03017

§ 371 Date: Mar. 6, 2013

(51) Int. Cl. H01L 21/02; H01L 29/20; H01L 21/78

(52) U.S. Cl. CPC H01L 21/0254; H01L 21/78; H01L 29/2003
USPC 257/615; 438/478; 438/460

(57) ABSTRACT

A semiconductor wafer, comprising multiple active areas suitable for providing semiconductor devices or circuits. Inactive areas separate the active areas from each other. The wafer has a stressed layer with a first surface, and another layer which is in contact with the stressed layer along a second surface of the stressed layer, opposite to the first surface. Multiple trench lines, extend in parallel to the first surface of the stressed layer in an inactive area and have a depth less than the thickness of the semiconductor wafer.

### FIELD OF THE INVENTION

This invention relates to methods for processing a semiconductor wafer, a semiconductor wafer and a semiconductor device.

### BACKGROUND OF THE INVENTION

The manufacturing of semiconductor devices typically involves the shaping of multiple independent circuits on a semiconductor wafer, in a manner that the circuits can be separated in a later stage of the manufacturing, e.g. by singulating (“dicing”) the semiconductor wafer in individual pieces (dice) of semiconducting material, each with a given electronic circuit or electronic device. The singulated dices can be subject to further processing, if so desired, such as testing and packaging the singulated circuits into an integrated circuit package.

The shaping of the multiple separate circuits normally involves the formation of a variety of patterned and unpatterned insulating, semi-conductive and conductive device regions and layers on a substrate formed by the unprocessed wafer. As part of the patterning, a photoresist layer is typically deposited on the top-surface of the wafer and patterned by a photolithographic or other process, thus creating regions in which the top-surface of the wafer is exposed and regions where the top-surface is not exposed. Such a patterning involves transferring a predefined pattern, e.g. in case of photolithography projecting an image of the desired pattern on the wafer surface. However, in case the wafer surface is deformed, e.g. not flat, the transferred pattern is distorted. Such surface deformations may have various causes.

For example, the deposition and patterning of different layers on the substrate may cause the surface to be uneven. U.S. Pat. No. 6,280,645 and U.S. Pat. No. 6,303,511 describe a wafer flattening process and system where the roughness of the surface is reduced by subjecting the surface to a plasma treatment. U.S. Pat. No. 6,254,718 describes a combined chemical-mechanical polishing (CMP) and plasma etching wafer flattening system where the roughness of the surface is reduced by subjecting the surface to CMP and plasma etching.

Also, stress in one or more layers of the wafer (besides leading to wafer fragility and a general difficult to subject the wafer to processing, such as back grinding and dicing) may lead to bow of the wafer and a corresponding distortion of the projected image. U.S. Pat. No. 6,770,504 discloses methods and structure for improving wafer bow control where a multi-layer stack of SiGe and B-doped Si is used to control and minimize the amount of bow. However, manufacturing such a stack is complex. In addition, the mechanical requirements imposed on the materials used required to reduce bow, may not be compatible with the electrical requirements imposed on the materials required for a proper performance of the semiconductor circuit.

### SUMMARY OF THE INVENTION

The present invention provides methods for processing a semiconductor wafer, a semiconductor wafer and a semiconductor device as described in the accompanying claims.

Specific embodiments of the invention are set forth in the dependent claims. These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1(a)-(c) schematically show top-views an example of an embodiment of a semiconductor wafer in a various stages of an example of a method according to the invention.

FIG. 2(a)-(h) schematically show cross-sectional side-views a part of an example of an embodiment of a semiconductor wafer in a various stages of an example of a method according to the invention.

FIGS. 3-5 schematically show top-views of various examples of trench-lines patterns which can be provided on a semiconductor wafer according to the invention.

### DETAILED DESCRIPTION OF THE PREFERRED EMBODIMENTS

Because the illustrated embodiments of the present invention may for the most part, be implemented using electronic components and circuits known to those skilled in the art, details will not be explained in any greater extent than that considered necessary for the understanding and appreciation of the underlying concepts of the present invention and in order not to obfuscate or distract from the teachings of the present invention.

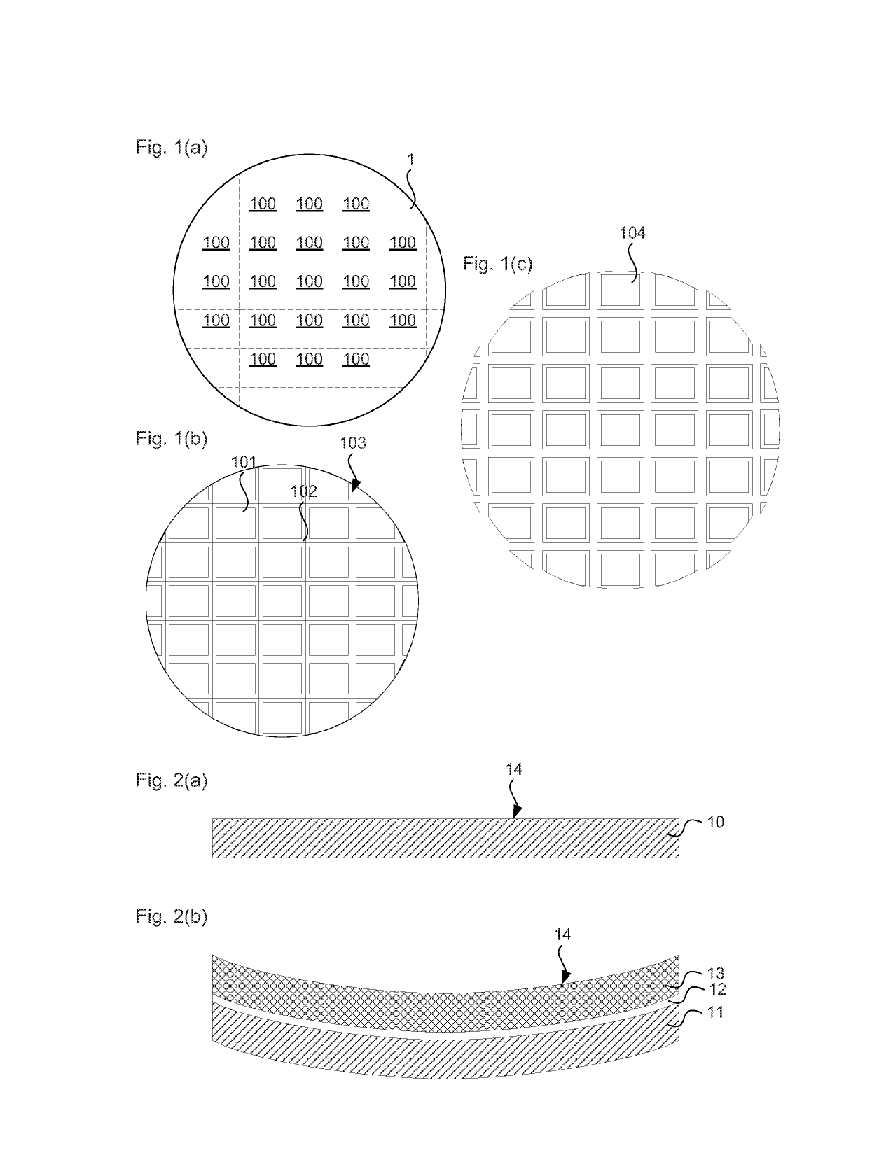

Referring to FIG. 1(a), a wafer 1 is shown therein. Multiple die areas 100 are indicated in this figure, which correspond to the individual dice. The die areas have a rectilinear shape and are arranged in a matrix array. However, it will be apparent that other shapes and arrangements may be used as well. As shown in FIG. 1(b), during manufacturing a part of the die area 100, the active device area 101, is occupied by the structures of the electronic circuit or electronic device of the respective die. For example a power transistor, such as a heterojunction transistor, may be provided on the die. Typically, a peripheral area 102 adjacent to the perimeter of the die area is left empty, such as to allow dicing along the scribe lines 103 without damage to the electronic circuit.

The peripheral area 102 is an inactive area because the peripheral area does not have circuit elements or connections of the electronic circuit or device in die area 101. However, the peripheral area 102 may contain some components independent from the electronic circuit or device in die area, such as wafer-level reliability and functionality test pads or test circuitry to facilitate wafer-level testing. It should be noted that the die area may contain other inactive areas, such as those that separate different components, e.g. core an peripherals from each other.

As shown in FIG. 1(c) after singulation, the semiconductor wafer is no longer an integral block with multiple independent circuits or devices but is separated in individual dice 104 of semiconducting material, each with a respective electronic circuit or electronic device. The singulated dices 104 can be subject to further processing, if so desired, such as testing and packaging the singulated circuits into an integrated circuit package.

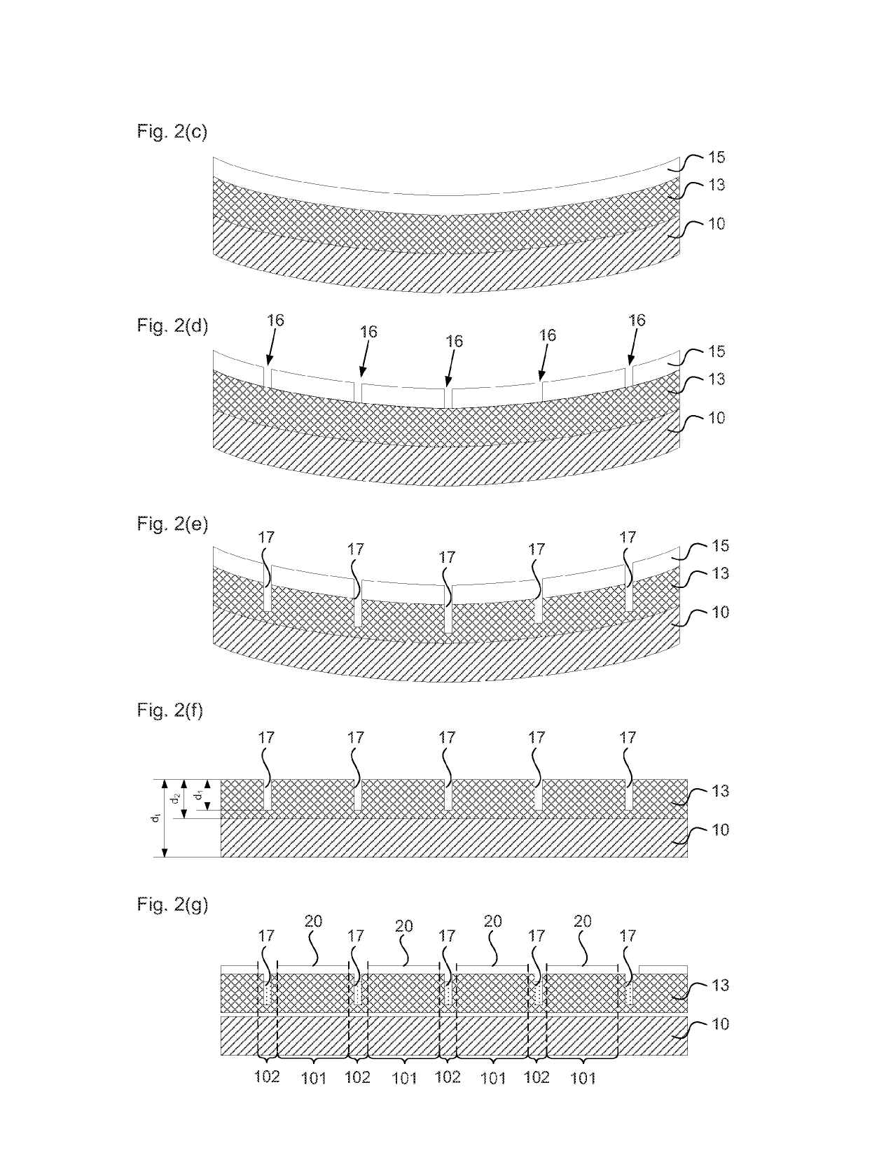

An example of a method or processing a semiconductor wafer will be described hereinbelow with reference to FIG. 2, and the various stages in which the example of an embodiment of a semiconductor wafer is shown in FIG. 2.

As shown in FIG. 2(a) and (b), a semiconductor wafer 10 may be provided with a curvature in at least one direction and the curvature may be reduced thereafter. The curvature may be in one direction only, i.e. the wafer will not show curvature in a cross-section perpendicular to that direction and mathematically speaking has a cylindrical shape obtained from an open, not straight curve. Without wishing to being bound to this theory, it is believed that this is for example, the case when the curvature is caused by an anisotropic lattice mismatch between layers in only one direction such as for example for GaN epitaxial layers deposited on a Si(111) substrate. Alternatively, the curvature may be in two directions, causing the wafer to have a bowl-like shape or a saddle-like shape, for example in case the curvature is caused by a lattice mismatch in multiple directions between layers or in case the curvature is caused by several layers each having a lattice mismatch relative to the adjacent layers in only one direction but the directions differing between the layers.

The curvature may for example be caused by tensile or compressive stress in a layer of the wafer. Such a layer may have been provided on top of the initial wafer material or be part of the initial wafer material, as shown in FIG. 2(b). For example, the initial wafer may be an compound substrate wafer with multiple layers, such as a silicon on insulator substrate or a Si substrate with a GaN heteroepitaxial layer, which for example is manufactured prior to the manufacturing process of the integrated circuits is started, and optionally on a different location. Alternatively, the stressed layer may be provided as integral part of the manufacturing process of the integrated circuits on the initial wafer, for example by a blanket deposition of a stressed layer material. The stressed layer may be un-patterned or have been patterned prior to reducing the curvature.

For example, a compound substrate wafer may be provided which was obtained by growing on a silicon base layer or substrate an epitaxial layer of gallium nitride (GaN). Referring to FIG. 2(a) for example an initial substrate 11 may be provided. In this example, the substrate 11 is a silicon substrate with the top surface being formed by the (111) orientation of the silicon lattice, but the substrate 11 can be formed from other materials or with other orientations, for example silicon carbide or a suitable nitride of a III-V semiconductor material such as one or more materials in the group consisting of: binary III-nitride material, ternary III-nitride material, quaternary III-nitride material or alloys or compounds thereof (such as AlN, InN, GaN, or the like). The substrate 11 may be formed by growing the substrate 11 on another, e.g. sapphire, substrate, for example using by a High Vapour Process Epitaxy (HVPE) process, and thereafter separating the substrate 102 from the other substrate according to any suitable separation or cleavage technique known in the art. The substrate 11 may have been separated from the other substrate before further manufacturing of the lateral power transistor device or, in particular in relation to a substrate formed from a suitable nitride of a III-V semiconductor material, the skilled person should also appreciate that the substrate 11 may remain disposed on the sapphire substrate and be processed using the processing steps described hereinbelow, after which the gallium nitride substrate can be separated from the sapphire substrate.

As shown FIG. 2(b), a one or more intermediate layers 12 may be disposed on the initial substrate 11. The layers may be a single layer, such as consisting of a seed layer or a multi-layer stack, such as a stack comprising a seed layer and one or more transitional layers, such as a stack of AlN—GaN—AlN. The seed layer provides an ordered surface for further growth of subsequent layers on top of the seed layer. The seed layer may for example be highly resistive or isolating and for instance be formed from a suitable nitride of a III-V semiconductor material, such as AlN. On the seed layer a transitional layer or stack of layers may be provided, e.g. by suitable epitaxial growth processes, which serves to match the lattice of the substrate to the lattice of the epitaxial layers grown on the intermediate layer(s) and/or electrically isolate the structures formed above the intermediate layer from the substrate. The seed layer may for instance be formed from a suitable nitride of a III-V semiconductor material, such as aluminium gallium nitride layer or a AlInN layer or any combination of AlGaINN.

The formation of the intermediate layer(s) 12 may be followed by disposal of a semi-insulating layer 13 (FIG. 2(b)) on top of the intermediate layer 12, for example by epitaxial growth thereon. In this example, the semi-insulating layer 13 is p-type doped gallium nitride, where the dopant is magnesium (Mg). However, other dopants can be employed, for example, carbon (C) or iron (Fe) to increase the electrical resistance of the semi-insulating layer 108 or to develop a p-type behaviour by the layer. Alternatively, the semi-insulating layer 13 can be a layer of a suitable nitride of a III-V semiconductor material, for example: not-intentionally doped aluminium gallium nitride (AlGaN), not-intentionally doped indium gallium nitride (InGaN) or not-intentionally doped aluminium indium nitride (AlInN). If desired, other layers such as an aluminium gallium nitride or gallium nitride inter-layer (not shown) can be disposed on the substrate 102 using any suitable known technique prior to formation of the intermediate layer 12 and the semi-insulating layer 13.

In the shown example, the semi-insulating layer 13 exhibits compressive stress due to the mismatch in the lattice between the initial substrate 11, as occurs for example when a GaN hetero-epitaxial layer is grown on a Si(111) substrate. In such case, the lattice constant of GaN is smaller than that of Si(111) and in case of the growth of an GaN layer on the (111) surface of a Si bulk layer, with or without a seed layer between, the lattice constant of the GaN layer will differ from that of the (111) surface and the GaN will be exhibiting tensile stress. Although the exact value depends on the specific process parameters, typical percentages are between 10% and 20%, the mismatch between the GaN lattice and the Si(111) surface results in a curvature of the wafer and the exposed top-surface 14 thereof after growth of the stressed layer. Typical values that may be used are a Si substrate of several hundreds of micrometers thick, such as between 500 μm and 750 μm, for example 625 μm, a GaN nitride layer of 0.5 μm up to 10 μm resulting in a bow of 100-200 μm for a 6 inch wafer.

The curvature may be reduced in the semiconductor wafer by providing in inactive areas of the semiconductor wafer, such as the peripheral areas 102, multiple trench lines 17 extending at least partially in a stressed layer of the semiconductor wafer and in parallel with the surface of the stressed layer. The inactive areas of the die may be any areas which do not have electronic components or connections of the electronic circuit or device provided therein after manufacturing, such as for example the peripheral areas or insulating areas between active device areas. The inactive areas may be provided with other elements though, such as elements used for the processing of a substrate, such as alignment marks, structures for measuring dimensions of features (“CD bars”), electrical test structures, and the like or protective elements which serve to protect the circuit or device from post-fabrication environmental conditions, such as an edge ring seal around a die. In this respect, the active device areas are the areas of the die that are provided with the electronic components, such as transistors, capacitors, resistors, or the like, and/or connections of the electronic circuit or device.

The trenchlines may be provided in any manner suitable for the specific implementation. In the shown example, the trenchlines are provided in a compressively stressed layer (e.g. a GaN heteroepitaxial layer grown on a Si(111) substrate). As illustrated in FIGS. 2(c)-2(g), for example, the trenchlines may be provided prior to providing the electronic circuit 20. For instance, the unpatterned substrate may be provided with the trenchlines as follows. A blanket resist layer 15 is provided on the exposed top-surface of the stressed layer such as to cover the stressed layer and to protect the stressed layer 13 where covered by the resist layer 15, as shown in FIG. 2(c) The resist layer 15 is then patterned to expose the top-surface locally where the trenches are to be provided, resulting in a pattern 16 of corresponding to the pattern of trenchlines 17, as shown in FIG. 2(d). Subsequently, as shown in FIG. 2(e), the substrate may be exposed to an etching medium which removes the stressed layer where exposed, thus forming trenchlines 17 and reducing the curvature of the wafer. Thereafter, the resist layer 15 may be removed, resulting in the substrate of FIG. 2(f).

The trenchlines may have any shape and depth suitable for the specific implementation and the pattern may be any pattern suitable for the specific implementation. For example, the trenchlines may extend from the top-surface of the stressed layer into the stressed layer to a depth d₁ which is less than the thickness d₂ of the stressed layer 13. Although other values may be used, it has been found that a depth d₁ less than or equal to half the thickness d₂ already provides good results. In an example, in an Si(111)-GaN compound wafer with an initial curvature of 120 μm, trenches of 1 μm depth where provided in the GaN layer which had a thickness of about 5 μm, resulting in a reduced curvature of about 80 μm. The bow be accurately measured by mechanical or optical means, as known in the art of semiconductor manufacturing.

As illustrated in FIG. 2(g), after formation of the trenchlines 17 and the associated reduction of the curvature, the semiconductor wafer may be processed further. For example, the electronic circuit 20 may be formed on the substrate in the active area, suitable structures may be provided in the inactive areas. This is only illustrated schematically in FIG. 2(g), but it will be apparent to a skilled person that this may be implemented in any manner suitable for the specific application and involve more or less extensive further processing of the wafer. As shown, at least some material is provided in said trench lines in at least some stages of said further processing. For example, during the further processing the trenchlines 17 may be provided, at least partially with some material which covers the walls of the trenchlines, such as material deposited on the wafer which is not (entirely) removed from the trenches.

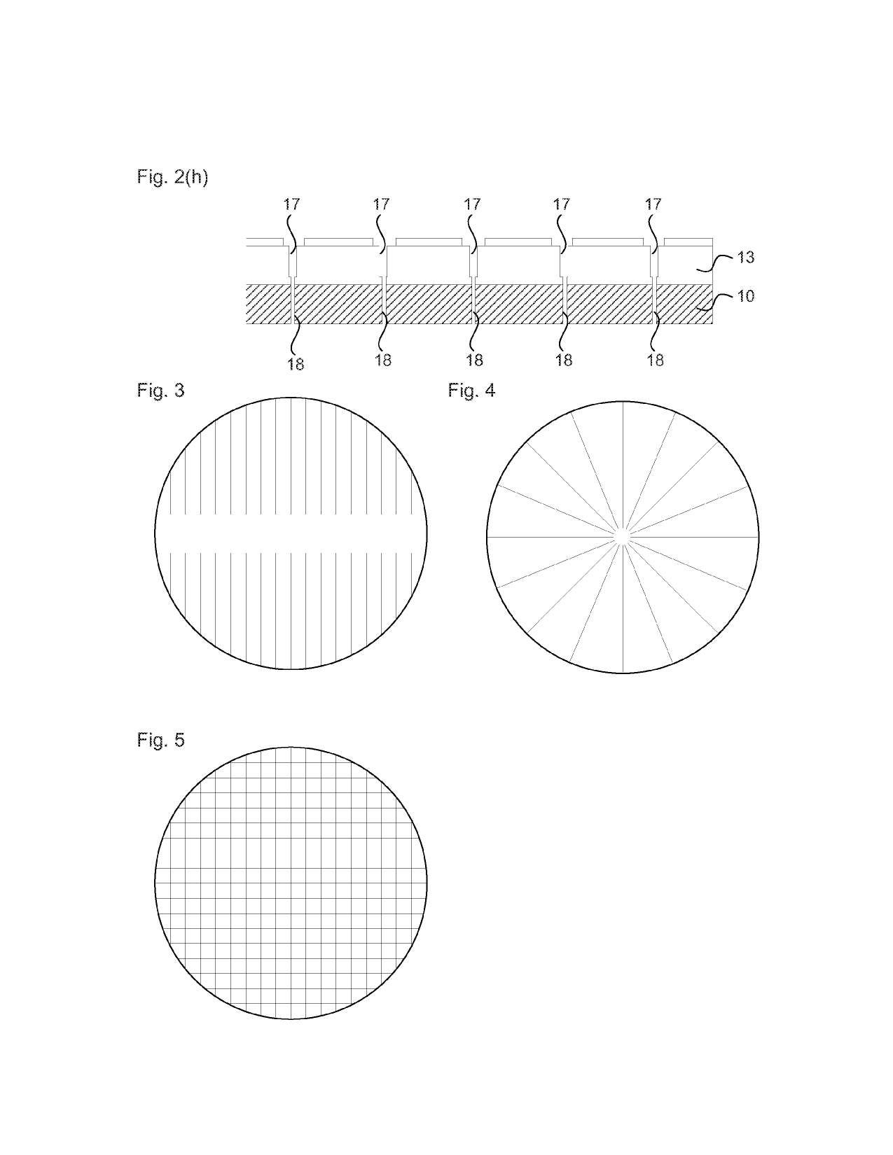

The trenchlines may be provided in any pattern suitable for the specific implementation. The wafer may be provided with multiple semiconductor devices or circuits 20 in respective active areas 101—as indicated in FIG. 2(g), and the trench lines be separated by at least one active area. For example, the trenchlines may be provided in a grid which separate the active areas, such as the rectangular grid shown in FIG. 1(b) or differently shape grids such as parallelogram-shaped, honeycomb-shape, etc. However other patterns may be used as well, such as a radial pattern as shown in FIG. 4 or patter of parallel lines. As shown in FIGS. 3 and 4, the trenchlines may extend over a part of the surface or as shown in FIG. 5 may extend between opposite sides of the wafer.

The trenchlines may as shown be continuous lines, however if suitable the trenchlines may be dashed or dotted.

The trenchlines may be provided in any density suitable for the specific implementation. For example, the multiple trench lines may be separated at least 1 mm from each other. As shown in FIG. 2(h) m after providing the devices or circuits, the wafer may be diced into separate dies. The dies may then be left as a bare die or be subjected to further processing, such as packaging. On the singulated dies trenchlines may be detectable, for example when as illustrated in FIG. 2(h) the trenchlines are wider than the width of the die saw with which the wafer is diced, resulting in the incisions 18 made by the die saw being narrower than the trenchlines and the cut-dice exhibiting a step in the side surface.

In the foregoing specification, the invention has been described with reference to specific examples of embodiments of the invention. It will, however, be evident that various modifications and changes may be made therein and that the appended claims are not limited to the shown examples.

For example, the semiconductor substrate described herein can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. A method for processing a semiconductor wafer, comprising:
providing the semiconductor wafer, the semiconductor wafer having a curvature in at least one direction;
reducing the curvature, said reducing comprising:
providing in inactive areas of the semiconductor wafer multiple trench lines extending at least partially in a stressed layer of the semiconductor wafer and in parallel with the surface of the stressed layer, the multiple trench lines having a depth less than the thickness of the semiconductor wafer,
the stressed layer being a III-nitride layer,
the trenchlines extending from the top-surface of the stressed layer into the stressed layer to a depth d1 which is less than the thickness d2 of the stressed layer.

2. A method as claimed in claim 1, comprising: providing the semiconductor wafer with a semiconductor device in an active area outside the inactive area.

3. A method as claimed in claim 2, comprising providing multiple semiconductor devices or circuits in respective active areas, and wherein the trench lines are separated by at least one active area.

4. A method as claimed in claim 1, wherein the multiple trench lines are separated at least 1 mm from each other.

5. (canceled)

6. (canceled)

7. A method as claimed in claim 1, wherein the stressed layer is compressively stressed.

8. A method as claimed in claim 1, comprising further processing said semiconductor wafer, and wherein at least some material is provided in said trench lines in at least some stages of said further processing.

9. A method for processing a semiconductor wafer, comprising:
providing a semiconductor wafer processed with a method of claim 1,
dicing the semiconductor wafer into separate dies.

10. A method as claimed in claim 9, comprising: subjecting at least one of the separate die to further processing.

11. A semiconductor wafer, comprising:
multiple active areas suitable for providing semiconductor devices or circuits;
inactive areas which separate the active areas from each other;
a stressed layer with a first surface; and
another layer which is in contact with the stressed layer along a second surface of the stressed layer, opposite to the first surface;
multiple trench lines, each extending parallel to the first surface of the stressed layer in an inactive area and having a depth less than the thickness of the semiconductor wafer,
the stressed layer being a III-nitride layer,
the trenchlines extending from the to surface of the stressed layer into the stressed layer to a depth d1 which is less than the thickness d2 of the stressed.

12. A wafer as claimed in claim 1, comprising semiconductor devices or circuits provided in active areas.

13. A semiconductor device, comprising a die singulated out of a semiconductor wafer as claimed in claim 9, on which die at least one trench-line of said semiconductor wafer is detectable.

14. A method as claimed in claim 1, wherein the depth d₁ of the trenchlines is less than or equal to half the thickness d₂ of the stressed layer.

15. A method as claimed in claim 1, comprising, after formation of the trenchlines and the associated reduction of the curvature, forming an electronic circuit on the substrate.

16. A method as claimed in claim 1, wherein the stressed layer is a GaN heteroepitaxial layer grown on a Si substrate.

17. A method as claimed in claim 1, the semiconductor wafer comprising one or more intermediate layers on a substrate.

18. A method as claimed in claim 17, the one or more intermediate layers comprising a seed layer.

19. A method as claimed in claim 18, the seed layer being formed from a suitable nitride of a III-V semiconductor material selected from the group of AlN, aluminium gallium nitride, AlInN or any combination of AlGaINN.

20. A method as claimed in claim 17, the one or more intermediate layers comprising a stack of a seed layer and one or more transitional layers.
